(19) United States
(12) Patent Application Publication
(10) Pub. No.: US 2024/0145431 A1
(43) Pub. Date: May 2, 2024

(54) Packaged Semiconductor Devices and Methods of Forming the Same

(71) Applicant: Taiwan Semiconductor Manufacturing Co., Ltd., Hsinchu (TW)

(72) Inventors: Yung-Lung Chen, Miaoli County (TW); Ming-Yun Liao, Zhunan Township (TW); Yi-Hsiu Chen, Hsinchu (TW); Wen-Chih Chiou, Taoyuan City (TW)

(21) Appl. No.: 18/151,150

(22) Filed: Jan. 6, 2023

Related U.S. Application Data
(60) Provisional application No. 63/420,264, filed on Oct. 28, 2022.

(51) Int. Cl. H01L 25/065; H01L 23/00; H01L 23/48; H01L 25/00

(52) U.S. Cl. CPC H01L 25/0652; H01L 23/481; H01L 24/08; H01L 25/50; H01L 2224/08145

(57) ABSTRACT

A method includes: attaching a first die and a second die to a substrate, the first die comprising a conductive via; forming a die spacer between the first die and the second die; thinning the first die and the second die, wherein after thinning the first die and the second die, the die spacer protrudes a first height above an upper surface of the first die; depositing an insulating layer over the first die and the second die; planarizing the insulating layer, wherein after planarizing, the insulating layer has a first thickness above the first die and a second thickness above the die spacer; attaching a third die and a fourth die to the first die and the second die; and attaching a support substrate to the third die and the fourth die.

### PRIORITY CLAIM AND CROSS-REFERENCE

This application claims the benefit of U.S. Provisional Application No. 63/420,264, filed on Oct. 28, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, and the like). For the most part, improvement in integration density has resulted from iterative reduction of minimum feature size, which allows more components to be integrated into a given area. As the demand for shrinking electronic devices has grown, a tendency for smaller and more creative packaging techniques of semiconductor dies has emerged.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of an integrated circuit die, in accordance with some embodiments.

FIG. 1B illustrates a cross-sectional view of a bridge die, in accordance with some embodiments.

FIG. 1C illustrates a cross-sectional view of a die stack, in accordance with some embodiments.

FIGS. 2, 3, 4, 5, 6, 7, 8, 9, 10, 11, 12, 13, 14, and 15 illustrate cross-sectional views of intermediate steps during processes for forming a packaged semiconductor device, in accordance with some embodiments.

FIGS. 16-18 illustrate cross-sectional views of intermediate steps during processes for forming a packaged semiconductor device, in accordance with some embodiments.

FIGS. 19A and 19B illustrate cross-sectional views of intermediate steps during processes for forming packaged semiconductor devices, in accordance with various embodiments.

FIGS. 20A-20C illustrate cross-sectional views of intermediate steps during processes for forming packaged semiconductor devices, in accordance with various embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide improved methods of bonding semiconductor components in a packaged semiconductor device, and packaged semiconductor devices formed by the same. In accordance with some embodiments, a plurality of first integrated circuit dies (e.g., a first level of integrated circuit dies) are attached to a carrier substrate, and die spacers (e.g., gap-fill dielectrics) are formed in gap regions between adjacent first integrated circuit dies. The first integrated circuit dies undergo processing in preparation for attaching second integrated circuit dies (e.g., a second level of integrated circuit dies) to the first integrated circuit dies. For example, semiconductor substrates of the first integrated circuit dies are recessed to expose conductive vias, which then protrude from the semiconductor substrates. The die spacers may also protrude from the semiconductor substrates of the first integrated circuit dies. An insulating layer (e.g., an oxide layer) is deposited over the first integrated circuit dies with a sufficient thickness that the protruding conductive vias and die spacers are covered. A planarization process is performed with improved effectiveness and efficiency by being performed on only the insulating layer, which remains covering the semiconductor substrates, the conductive vias, and the die spacers. Furthermore, bonding of the second integrated circuit dies (and, optionally, bridge or dummy dies) is improved. The packaged semiconductor device may undergo further processing, including similar steps to improve attachment of third integrated circuit dies. In accordance with the various embodiments, the packaged semiconductor device may be assembled at greater efficiency and increased yield (e.g., thereby reducing costs) and with an improved performance.

Various embodiments are described below in a particular context. Specifically, multiple levels of chips on wafer on substrate-type of system on integrated chip (SoIC) package is described. However, various embodiments may also be applied to other types of packaging technologies, such as, chip-on-wafer-on-substrate (CoWoS®) packages, die-die-substrate stacked packages, integrated fan-out (InFO) packages, and/or other types of semiconductor packages.

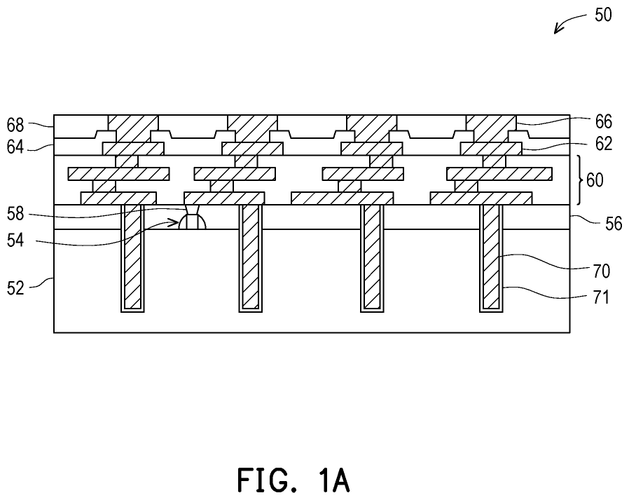

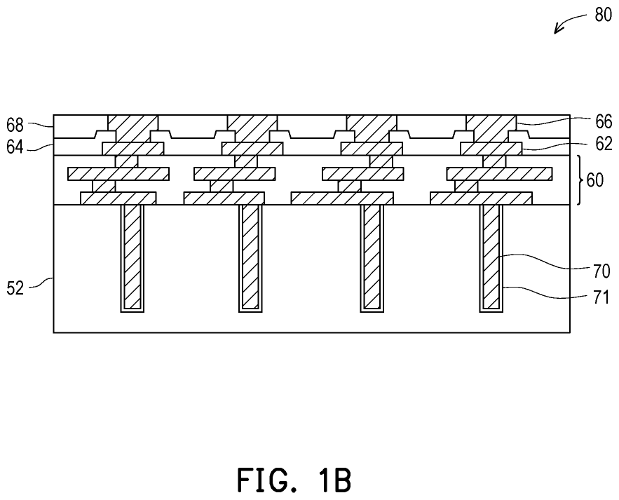

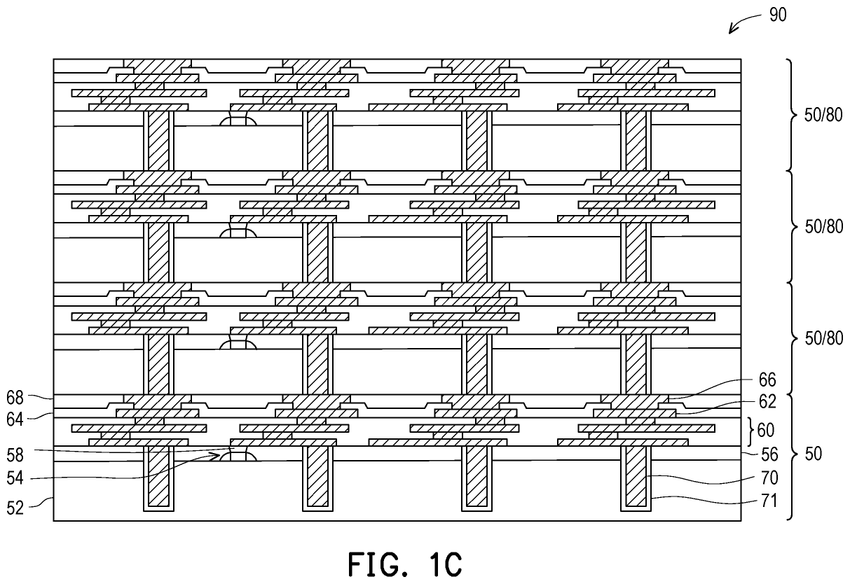

FIGS. 1A-1C illustrate cross-sectional views of exemplary layouts of an integrated circuit die 50, a bridge die 80, and a die stack 90, respectively. As illustrated and discussed further below, embodiments of various packaged semiconductor devices may include varieties and combinations of the integrated circuit dies 50, the bridge dies 80, and the die stacks 90.

FIG. 1A illustrates a cross-sectional view of an integrated circuit die 50, in accordance with some embodiments. One or more of the integrated circuit dies 50 will be packaged in subsequent processing to form various embodiments of a packaged semiconductor device. The integrated circuit die 50 may be a logic die (e.g., a central processing unit (CPU), a graphics processing unit (GPU), a system-on-a-chip (SoC), an application processor (AP), a microcontroller, or the like); a memory die (e.g., a dynamic random access memory (DRAM) die, a static random access memory (SRAM) die, or the like); a power management die (e.g., a power management integrated circuit (PMIC) die); a radio frequency (RF) die; a sensor die; a micro-electro-mechanical-system (MEMS) die; a signal processing die (e.g., a digital signal processing (DSP) die); a front-end die (e.g., an analog front-end (AFE) die); or a combination thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. In some embodiments, the integrated circuit die 50 includes a semiconductor substrate 52, such as silicon, doped or un-doped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used. The semiconductor substrate 52 has an active surface (e.g., the surface facing upwards in FIG. 1A), which may be referred to as a front-side, and an inactive surface (e.g., the surface facing downwards in FIG. 1A), which may be referred to as a back-side.

Devices (represented by a transistor) 54 may be formed at the front-side of the semiconductor substrate 52. The devices 54 may be active devices (e.g., transistors, diodes, or the like), capacitors, resistors, or the like. An inter-layer dielectric (ILD) 56 is on the front-side of the semiconductor substrate 52. The ILD 56 surrounds and may cover the devices 54. The ILD 56 may include one or more dielectric layers formed of materials such as phosphosilicate glass (PSG), boro-silicate glass (BSG), boron-doped phosphosilicate glass (BPSG), un-doped silicate glass (USG), or the like.

Conductive plugs 58 may be formed extending through the ILD 56. The conductive plugs 58 may be electrically and physically coupled to the devices 54. In embodiments in which the devices 54 are transistors, the conductive plugs 58 may be coupled to gates and/or source/drain regions (source/drain regions may refer to a source or a drain, individually or collectively, dependent upon the context) of the transistors. The conductive plugs 58 may be formed of tungsten, cobalt, nickel, copper, silver, gold, aluminum, the like, or combinations thereof.

Conductive vias 70 may be formed extending through the ILD 56 and into the semiconductor substrate 52. The conductive vias 70 may be subsequently exposed through the back-side of the semiconductor substrate 52, and may be used to provide electrical connections through the semiconductor substrate 52 (e.g., between the front-side of the semiconductor substrate 52 and the back-side of the semiconductor substrate 52). In some embodiments, the conductive vias 70 may be formed by forming recesses in the ILD 56 and/or the semiconductor substrate 52. The recesses may be formed by etching, milling, laser techniques, a combination thereof, or the like. A via liner 71 (e.g., a dielectric via liner) may be formed in the recesses, such as by thermal oxidation, atomic layer deposition (ALD), chemical vapor deposition (CVD), or the like. The via liner 71 may include oxides, such as silicon oxide, silicon oxynitride, or the like. A barrier layer and/or an adhesion layer (not separately illustrated) may then be conformally deposited in the recesses (e.g., along the via liner 71), such as by CVD, ALD, physical vapor deposition (PVD), a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the via liner 71, such as portions extending along top surfaces of the ILD 56 and/or the semiconductor substrate 52 are removed from the surfaces of the ILD 56 and/or the semiconductor substrate 52 by a planarization process, such as a chemical-mechanical polish (CMP), a grinding process, an etch-back process, or the like. Remaining portions of the the barrier layer, the adhesion layer, and/or the conductive fill material form the conductive vias 70.

An interconnect structure 60 is formed on the ILD 56, the conductive plugs 58, and the conductive vias 70. The interconnect structure 60 interconnects the devices 54 to form integrated circuits. In some embodiments, the interconnect structure 60 may be formed by metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58, and are electrically coupled to the conductive vias 70.

The integrated circuit die 50 further includes pads 62, such as aluminum pads, to which external connections are made. The pads 62 are on the front-side of the semiconductor substrate 52, such as in and/or on the interconnect structure 60. Solder regions (e.g., solder balls or solder bumps) may be disposed on the pads 62. The solder regions may be used to perform chip probe testing on the integrated circuit die 50. Chip probe testing may be performed on the integrated circuit die 50 to ascertain whether the integrated circuit die 50 is a known good die (KGD). Thus, only integrated circuit dies 50, which are KGDs, undergo subsequent processing and are packaged. Dies that fail the chip probe testing, are not packaged. After testing, the solder regions may be removed in subsequent processing steps.

One or more passivation films 64 are on the integrated circuit die 50, such as on portions of the interconnect structure 60 and the pads 62. Openings are formed extending through the passivation films 64 to the pads 62. Die connectors 66, such as conductive pillars (e.g., formed of a metal such as copper), are formed in the openings extending through the passivation films 64. The die connectors 66 may be physically and electrically coupled to respective ones of the pads 62. The die connectors 66 may be formed by plating, or the like. In some embodiments, the die connectors 66 may be formed from materials and by processes the same as or similar to the conductive vias 70. The die connectors 66 are electrically coupled to the integrated circuits of the integrated circuit die 50.

A dielectric layer 68 may (or may not) be on the front-side of the semiconductor substrate 52, such as on the passivation films 64 and around the die connectors 66. The dielectric layer 68 laterally encapsulates the die connectors 66, and the dielectric layer 68 is laterally coterminous with the semiconductor substrate 52. The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed by spin coating, lamination, CVD, or the like. Initially, the dielectric layer 68 may bury the die connectors 66, such that a topmost surface of the dielectric layer 68 is above topmost surfaces of the die connectors 66. In some embodiments, solder regions may be formed on the die connectors 66, and the dielectric layer 68 may bury the solder regions. In some embodiments, the die connectors 66 are exposed through or protrude above the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

FIG. 1B illustrates a cross-sectional view of a bridge die 80, in accordance with some embodiments. One or more of the bridge dies 80 may be packaged in subsequent processing to form various embodiments of a packaged semiconductor device. Within the packaged semiconductor device, the bridge die 80 may serve as a passive component (e.g., lacking active devices, such as transistors, diodes, capacitors, resistors, or the like) which may facilitate electrical connections, such as cross bonding, between other components (e.g., the integrated circuit dies 50, other bridge dies 80, and/or the die stacks 90). As illustrated, the bridge die 80 may be formed similarly and have most of the same or similar features as described above in connection with the integrated circuit die 50, albeit lacking, e.g., active components, conductive plugs, and surrounding inter-layer dielectrics. For example, the bridge die 80 may include a substrate 52 comprising a semiconductor material and/or other suitable materials, an interconnect structure 60 comprising metal lines and vias formed through one or more dielectric layers and/or through the substrate 52, and conductive vias 70 extending at least partially through the substrate 52. The bridge die 80 may further include some or all of other features described above in connection with the integrated circuit die 50, such as pads 62, a passivation layer 64, die connectors 66, and a dielectric layer 68.

FIG. 1C illustrates a cross-sectional view of a die stack 90, in accordance with some embodiments. One or more of the die stacks 90 may be packaged in subsequent processing to form various embodiments of a packaged semiconductor device. The die stack 90 may have a single function (e.g., a logic die, a memory die, or the like), or may have multiple functions. In some embodiments, the die stack 90 is a memory device such as an SRAM stack. As illustrated, the die stack 90 is a stacked device that includes multiple integrated circuit dies 50. In some embodiments, the die stack 90 may further include one or more bridge dies 80 (e.g., lacking active devices). For example, the die stack 90 may be a memory device that includes multiple memory dies, such as an SRAM stack including multiple SRAM dies, or the like. Each of the components (e.g., integrated circuit dies 50 and/or bridge dies 80) in the die stack 90 may (or may not) have any or all of the structures illustrated in FIGS. 1A and 1B.

In some embodiments, the integrated circuit dies 50 of the die stack 90 are attached to one another in a face-to-back arrangement, with conductive vias 70 of an overlying integrated circuit die 50 being physically and electrically coupled with die connectors 66 of an underlying integrated circuit die 50. Although illustrated such that the die stack 90 includes four integrated circuit dies 50, the die stack 90 may include any number of the integrated circuit dies 50, such as more or less than four of the integrated circuit dies 50. The integrated circuit dies 50 of the die stack 90 may be bonded to one another by dielectric-to-dielectric bonds and metal-to-metal bonds. As an example, a first integrated circuit die 50 is disposed face up, and a second integrated circuit die 50 is placed over the first integrated circuit die 50 and also disposed face up such that a back-side of the second integrated circuit die 50 faces a front-side of the first integrated circuit die. This may be referred to as a face-to-back configuration (F2B).

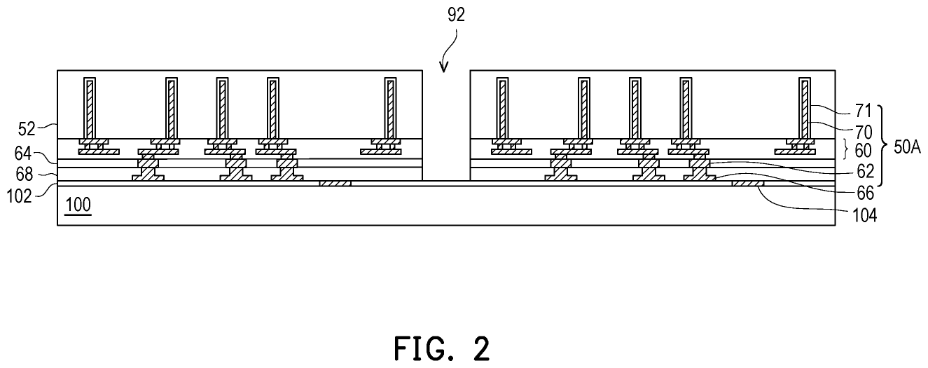

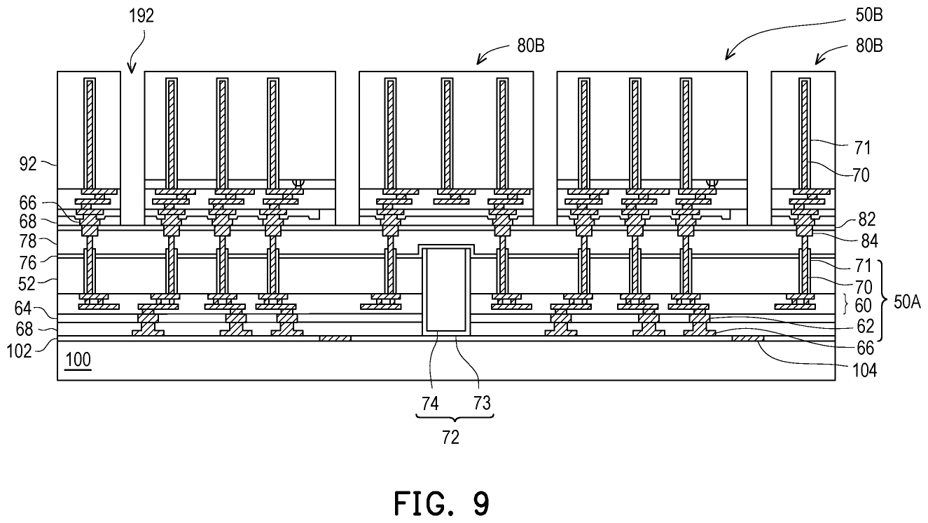

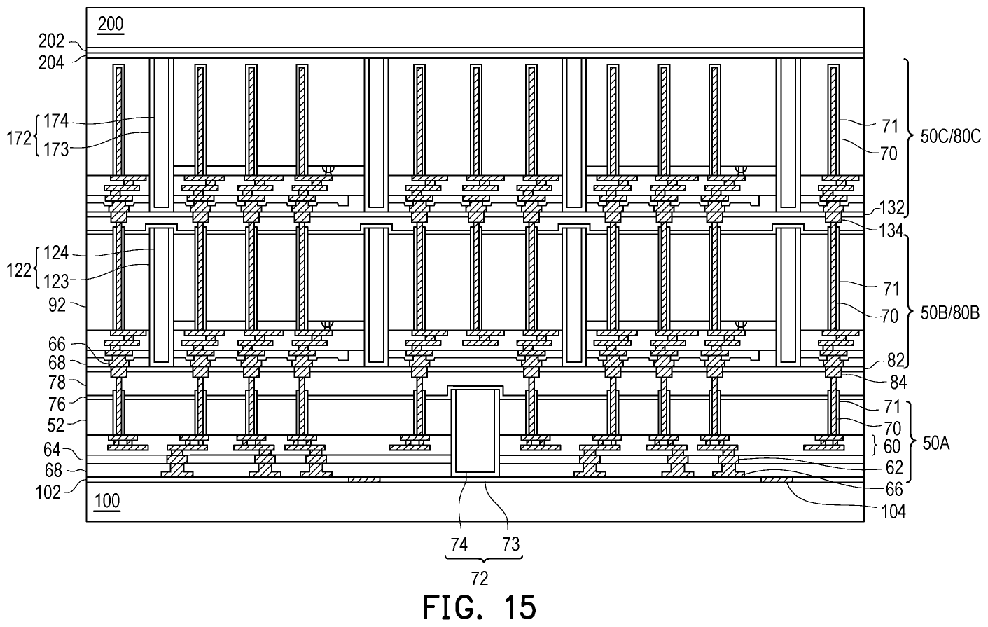

FIGS. 2 through 15 illustrate embodiments of forming a packaged semiconductor device having multiple levels of integrated circuit dies 50 and bridge dies 80 (see, e.g., FIG. 15) bonded to one another. For example, a first level comprising first integrated circuit dies 50A may be attached to a carrier substrate 100 (see FIG. 2), a second level comprising second integrated circuit dies 50B and second bridge dies 80B may be attached to the first integrated circuit dies 50A (see FIG. 9), and a third level comprising third integrated circuit dies 50C and third bridge dies 80C may be attached to the second integrated circuit dies 50B (see FIG. 15). In accordance with some embodiments, the integrated circuit dies 50 and/or the bridge dies 90 may be attached by dielectric-to-dielectric bonds and metal-to-metal bonds. Optionally, additional levels comprising integrated circuit dies 50 and/or bridge dies 50 may be included in the structure. In some embodiments, a support substrate 200 (see FIG. 15) is bonded to the integrated circuit dies 50 and the bridge 80 by dielectric-to-dielectric bonds, such as by fusion bonding.

In FIG. 2, a first level of first integrated circuit dies 50A is attached to a carrier substrate 100. The first integrated circuit dies 50A may be bonded to the carrier substrate 100 by bonding the dielectric layers 68 of the integrated circuit dies 50A to a bonding layer 102 on the carrier substrate 100. As illustrated, a gap region 92 may be interposed between adjacent ones of the first integrated circuit dies 50A. The carrier substrate 100 may be a glass carrier substrate, a ceramic carrier substrate, a wafer (e.g., a silicon wafer), or the like. The carrier substrate 100 may provide structural support during subsequent processing steps and in the completed device (unless removed). Although two of the first integrated circuit dies 50A are illustrated, any number of the first integrated circuit dies 50A may be attached to the carrier substrate 100, whether within an individual packaged semiconductor device or multiple packaged semiconductor devices that will eventually be singulated. In some embodiments (not specifically illustrated), the first level may include first bridge dies 80A (see FIG. 1B) attached to the carrier substrate 100 and adjacent to the first integrated circuit dies 50A.

In some embodiments, the first integrated circuit dies 50A may be bonded to the carrier substrate 100 using a suitable technique, such as dielectric-to-dielectric bonding (referred to as fusion bonding), or the like. The bonding layer 102 may be an oxide layer, such as silicon oxide (e.g., a high density plasma (HDP) oxide or the like), that is formed on a surface of the carrier substrate 100 prior to bonding using, for example, CVD, ALD, PVD, thermal oxidation, or the like. Other suitable materials may be used for the bonding layer 102.

The dielectric-to-dielectric bonding process may further include applying a surface treatment to the dielectric layers 68 and/or the bonding layer 102. The surface treatment may include a plasma treatment. The plasma treatment may be performed in a vacuum environment. After the plasma treatment, the surface treatment may further include a cleaning process (e.g., a rinse with deionized water or the like) that may be applied to the dielectric layers 68 and/or the bonding layer 102. The first integrated circuit dies 50A are then aligned with the carrier substrate 100 (such as being aligned relative to alignment marks 104 disposed in the bonding layer 102). The first integrated circuit dies 50A and the carrier substrate 100 are pressed against each other to initiate a pre-bonding of the dielectric layers 68 and the bonding layer 102. The pre-bonding may be performed at room temperature (e.g., between about 21° C. and about 25° C.). After the pre-bonding, an annealing process may be applied by, for example, heating the integrated circuit dies 50A and/or the carrier substrate 100 to a temperature of about 170° C. to about 500° C.

In some embodiments, alignment marks 104 may be formed in the bonding layer 102 on the carrier substrate 100, and may be used to align the first integrated circuit dies 50A with respect to the carrier substrate 100. The alignment marks 104 may be formed of metals, metal alloys, metal compounds or the like. The alignment marks 104 may be formed of materials having high contrast to the materials surrounding the alignment marks 104, such as the materials of the bonding layer 102. In some embodiments, the alignment marks 104 may be formed of or may include copper, a copper alloy, tungsten, nickel, or the like. Each of alignment marks 104 may include a metal material, and may or may not include an adhesion layer underlying and lining the metal material. The adhesion layer may be formed of or comprise titanium, titanium nitride, tantalum, tantalum nitride, or the like. The formation process may include depositing the adhesion layer (if included) as a conformal layer using PVD, and depositing a metallic material on the adhesion layer. The metallic material may be deposited by a plating process, such as an electro-chemical plating (ECP) process. A planarization process, such as a CMP may be performed to remove excess portions of the adhesion layer and the metallic material, leaving the alignment marks 104.

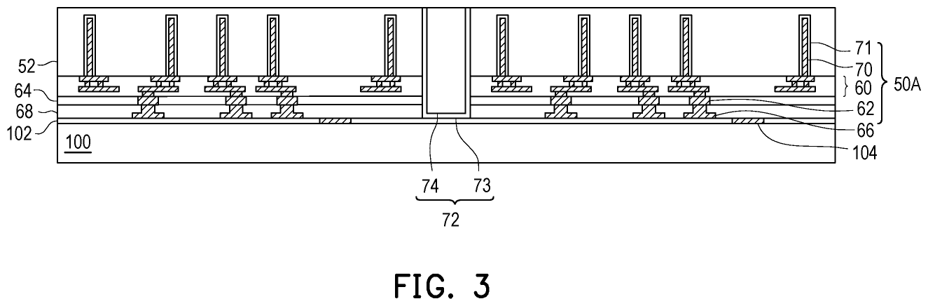

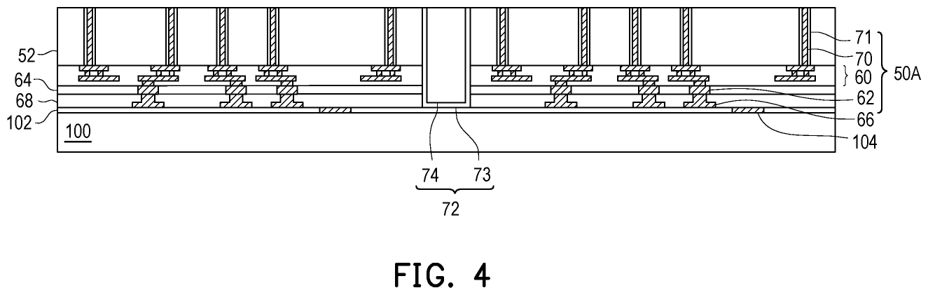

In some embodiments (not specifically illustrated), individual first integrated circuit dies 50A may have different thicknesses. As such, after the first integrated circuit dies 50A are attached to the carrier substrate 100, a planarization process may be performed to level back-side surfaces of the first integrated circuit dies 50A with one another. The planarization process may be a CMP, a grinding process, an etch-back process, or the like. In some embodiments, this planarization process may be performed later, such as during other planarization processes discussed below (see FIGS. 3-4).

In FIG. 3, die spacers 72, which include a liner layer 73 and a gap-fill material 74, are formed on the integrated circuit dies 50A and the carrier substrate 100 in the gap region 92, in accordance with some embodiments. The die spacer 72 (e.g., collectively, the liner layer 73 and the gap-fill material 74) may also be referred to as a gap-filling layer. The liner layer 73 may be formed of a dielectric material having good adhesion to the bonding layer 102 and the first integrated circuit dies 50A. In some embodiments, the liner layer 73 is formed of a nitride-containing material, such as silicon nitride, or an oxide-containing material, such as silicon oxide. The liner layer 73 may be deposited as a conformal layer. For example, the liner layer 73 may be deposited by a conformal deposition process, such as ALD, CVD, or the like.

The gap-fill material 74 may be formed of a material different from the material of the liner layer 73. In some embodiments, the gap-fill material 74 may be formed of silicon oxide, silicon carbide, silicon nitride, silicon oxynitride, silicon oxycarbonitride, PSG, BSG, BPSG, or the like. For example, the gap-fill material 74 may be formed of any of the above oxide-containing materials, such as silicon oxide. The gap-fill material 74 may be formed using CVD, high-density plasma CVD (HDPCVD), flowable CVD, spin-on coating, or the like. The gap-fill material 74 may fill remainders of the gap regions 92 between adjacent first integrated circuit dies 50A. After the liner layer 73 and the gap-fill material 74 are deposited, a planarization process, such as a CMP, a grinding process, an etch-back process, the like, or combinations thereof, is performed to remove excess portions of the liner layer 73 and the gap-fill material 74, thereby exposing the first integrated circuit dies 50A.

In FIG. 4, a thinning process is applied to back-sides of the first integrated circuit dies 50A and the die spacer 72 (e.g., the liner layer 73 and the gap-fill material 74). The thinning process may include a planarization process (e.g., a mechanical grinding, a CMP, or the like), an etch-back process, combinations thereof, or the like. In accordance with some embodiments, the thinning process may expose the conductive vias 70 and the via liner 71.

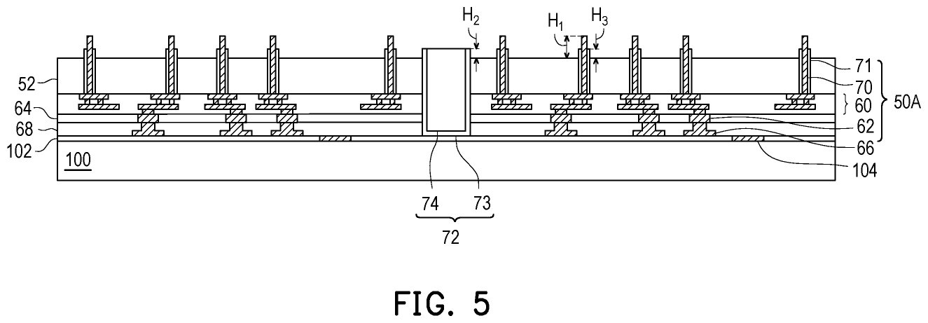

In FIG. 5, the semiconductor substrates 52 of the integrated circuit dies 50 are recessed so that the respective conductive vias 70 protrude above back surfaces of the semiconductor substrates 52. The semiconductor substrates 52 may be recessed by suitable etching processes, which may include isotropic etching processes such as wet etching, anisotropic etching process such as dry etching, or the like. The etching process may be selective for etching the material of the semiconductor substrates 52, while the conductive vias 70 remain substantially unetched. In some embodiments, the etching process may etch the via liner 71, the liner layer 73, and the gap-fill material 74 by greater rates than the conductive vias 70 and by lesser rates than the semiconductor substrate 52.

In some embodiments, after performing the etching process, the conductive vias 70 may protrude above the semiconductor substrates 52 by a height H₁ in a range from 0.6 μm to 1 μm. In addition, the die spacer 72 (e.g., the liner layer 73 and the gap-fill material 74) may protrude above the semiconductor substrates 52 by a height H₂, and the via liner 71 may protrude above the semiconductor substrate 52 by a height H₃. The heights H₂ and H₃ may be the same or different, wherein each is in a range from 0.2 μm to 0.6 μm. In some embodiments, the height H₂ may be less than the height H₃.

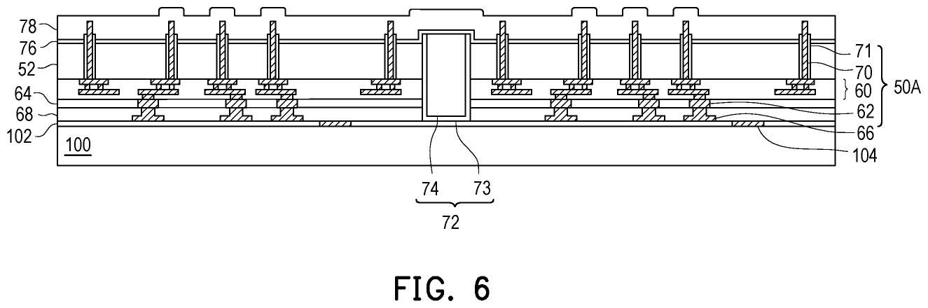

In FIG. 6, after recessing the semiconductor substrates 52, one or more insulating layers, such as an insulating layer 76 and an insulating layer 78, are formed over the recessed semiconductor substrates 52 with a thickness that also surrounds and covers the conductive vias 70 and the die spacers 72. The insulating layers 76, 78 provide isolation between the conductive vias 70, and may be used in subsequent dielectric-to-dielectric bonding processes for attaching various other dies to the first integrated circuit dies 50A. Each of the insulating layers 76, 78 is formed by depositing insulating material on the exposed upper surfaces (e.g., back-sides) of the first integrated circuit dies 50A. The insulating material may be formed of silicon oxide, silicon carbide, silicon oxynitride, silicon oxycarbonitride, PSG, BSG, BPSG, the like, or a combination thereof. The insulating material may be deposited by CVD, ALD, spin-on coating, or the like.

For example, the insulating layer 76 may be silicon nitride or silicon oxide and conformally deposited over the semiconductor substrates 52 and the die spacer 72 (e.g., the liner layer 73 and the gap-fill material 74). Although not specifically illustrated, in some embodiments, the insulating layer 76 may also be deposited along exposed surfaces of the conductive vias 70 and the via liner 71 (e.g., sidewalls and/or upper surfaces). In some embodiments, the insulating layer 76 is formed as a thermal oxide and, optionally, nitridated in a post-deposition treatment process. The insulating layer 78 may be silicon oxide or silicon nitride (e.g., a same or different material as the insulating layer 76) and conformally deposited over the insulating layer 76. In accordance with some embodiments, the insulating layer 78 may have a thickness above the semiconductor substrates in a range from 1 μm to 2 μm and a thickness above the conductive vias 70 in a range from 1 μm to 2 μm.

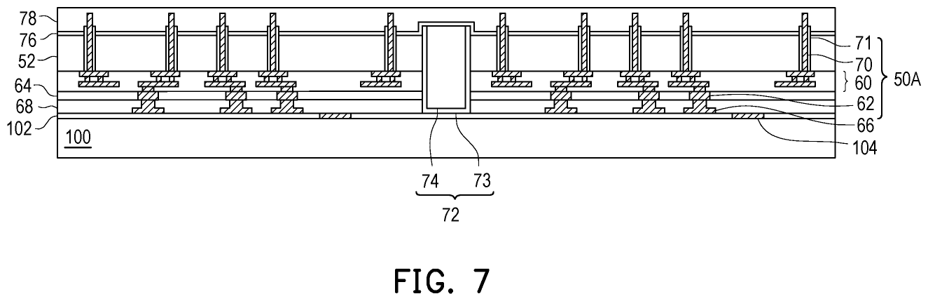

In FIG. 7, a planarization process is performed to level an upper surface of the insulating layer 78. The planarization process may be a CMP, a grinding process, an etch-back process, combinations thereof, or the like. In accordance with some embodiments, the planarization process is halted before reaching the conductive vias 70 or the planarization process may continue so that the insulating layer 78 is level with the conductive vias 70. As illustrated, after planarizing the insulating material, a planarized upper surface of the insulating layer 78 may be above top surfaces of the conductive vias 70, the insulating layer 76, the liner layer 73, and the gap-fill material 74. For example, in some embodiments, the insulating layer 78 may have a thickness above the semiconductor substrates 52 in a range from 1 μm to 1.5 μm, the insulating layer 78 may have a thickness above the conductive vias 70 in a range from 0.2 μm to 0.9 μm, and the insulating layer 78 may have a thickness above the die spacer 72 (or above the insulating layer 76) in a range from 0.8 μm to 1.3 μm.

Benefits are achieved by the top surfaces of the die spacer (e.g., the liner layer 73 and the gap-fill material 74), the insulating layer 76 (if present), and the conductive vias 70 remaining covered by the insulating layer 78 during and after the planarization process. For example, the CMP and/or etch-back processes of the planarization process may be more efficient and result in a flatter planarized surface because the planarization process is performed on a single material rather than on multiple materials (e.g., having varying etch selectivities). As a result, the planarized surface (e.g., the upper surface of the insulating layer 78) is flatter and smoother than if the planarized surface included the insulating layer 78 as well as the gap-fill material 74, the liner layer 73, and/or the insulating layer 76.

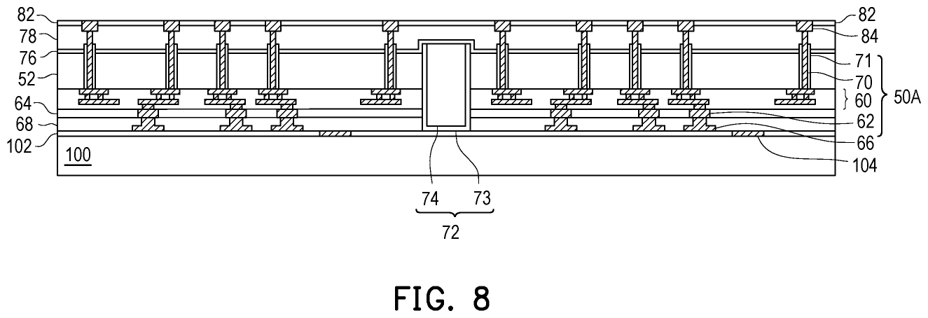

In FIG. 8, optionally, a dielectric bond layer 82 and bond pads 84 are formed over the insulating layer 78 and the conductive vias 70. In some embodiments, the dielectric bond layer 82 may be formed of an oxide (e.g., silicon oxide), a nitride (e.g., silicon nitride), an oxynitride (e.g., silicon oxynitride), or the like using a suitable process. Openings may be formed through the dielectric bond layer 82 and partially through the insulating layer 78 to expose the conductive vias 60. The bond pads 84 are then formed in the openings. In some embodiments, the bond pads 84 may include dummy bond pads, which are not coupled to any metal features (e.g., the conductive vias 60) of the integrated circuit dies 50.

To form the bond pads 84, openings may be formed in the dielectric bond layer 82 using acceptable photolithography and etching techniques. The openings may be formed extending through the insulating layer 78. A liner layer, a barrier layer, an adhesion layer, and/or a conductive fill material (not separately illustrated) may be formed in the openings and may be used to form the bond pads 84. The liner layer, the barrier layer, and the adhesion layer may be formed by ALD, PVD, CVD, thermal oxidation, or the like. The conductive fill material may be formed by plating, such as electroplating or electroless plating, or the like. In some embodiments, the liner layer may include oxides, such as silicon oxide, silicon oxynitride, or the like. The barrier layer and the adhesion layer may include titanium, titanium nitride, tantalum, tantalum nitride, or the like. The conductive fill materials may include copper, a copper alloy, silver, gold, tungsten, ruthenium, cobalt, aluminum, nickel, or the like. A planarization process such as a CMP may be performed to remove excess portions of the liner layer, a barrier layer, an adhesion layer, and/or a conductive fill material, until the dielectric bond layer 82 is exposed. The remaining portions of the liner layer, the barrier layer, the adhesion layer, and/or the conductive fill material form the bond pads 84, which are subsequently used for bonding. The dielectric bond layer 82 (and the insulating layer 78) may provide isolation between the conductive vias 70 and between the bond pads 84, and the dielectric bond layer 82 may be used in subsequent dielectric-to-dielectric bonding processes used to bond additional dies to the integrated circuit dies 50A.

In FIG. 9, a second level of second integrated circuit dies 50B and second bridge dies 80B is bonded to the dielectric bond layers 82 and the bond pads 84 on the integrated circuit dies 50A, in accordance with some embodiments. As illustrated, the second level may include gap regions 192 interposed between adjacent ones of the second integrated circuit dies 50B and the second bridge dies 80B. In the illustrated embodiments, the second integrated circuit dies 50B and the second bridge dies 80B are bonded to the first integrated circuit dies 50A by dielectric-to-dielectric bonds and/or metal-to-metal bonds. In some embodiments (not specifically illustrated), dummy dies (e.g., instead of some of the second bridge dies 80B) may be bonded to the first integrated circuit dies 50A by fusion bonding (e.g., dielectric-to-dielectric bonding).

In accordance with some embodiments (not specifically illustrated), some of the second bridge dies 80B may be dummy dies, such as thermal dissipation dies, to facilitate heat transfer from adjacent integrated circuit dies 50. For example, the dummy dies may be formed of homogenous materials, and may be free from devices, metal lines, and the like. A substrate of the dummy die may be formed of one or more materials having high thermal conductivities such as silicon, ceramic, heat conductive glass, metals such as copper or iron, or the like. A dielectric bond layer of the dummy die may be formed on the substrate and may be used to attach the dummy die to the first integrated circuit dies 50A. In some embodiments, the dielectric bond layer may be formed of materials such as silicon oxide, silicon nitride, silicon carbide, silicon carbon nitride, silicon oxygen nitride, silicon oxygen carbon nitride, combinations thereof, or the like.

The second integrated circuit dies 50B are bonded to the first integrated circuit dies 50A through the dielectric layers 68 and the die connectors 66 of the second integrated circuit dies 50A and the dielectric bond layer 82 and the bond pads 84 along the first integrated circuit dies 50A. Similarly, the second bridge dies 80B are bonded to the first integrated circuit dies 50A through the dielectric layers 68 and the die connectors 66 of the second bridge dies 80B and the dielectric bond layer 82 and the bond pads 84 along the first integrated circuit dies 50A. A desired type and quantity of the second integrated circuit dies 50B the second bridge dies 80B are adhered on each of the first integrated circuit dies 50A. In the illustrated embodiment, multiple second bridge dies 80B are adhered adjacent to each of the second integrated circuit dies 50B, however, other suitable arrangements may be utilized.

The second integrated circuit dies 50B may be logic devices, such as central processing units (CPUs), graphics processing units (GPUs), systems-on-chips (SoCs), microcontrollers, or the like. In some embodiments, the second integrated circuit dies 50B may be memory devices, such as dynamic random access memory (DRAM) dies, static random access memory (SRAM) dies, hybrid memory cube (HMC) modules, high-bandwidth memory (HBM) modules, or the like. As discussed above, the second bridge dies 80B may be interposers containing redistribution structures or functional devices such as memory devices similar to those listed above. The second integrated circuit dies 50B and the second bridge dies 80B may be formed in processes of a same technology node, or may be formed in processes of different technology nodes. For example, the second integrated circuit dies 50B may be of a more advanced process node than the second bridge dies 80B. Similarly, the second integrated circuit dies 50B and the first integrated circuit dies 50A may be formed in processes of a same technology node, or may be formed in processes of different technology nodes. Other combinations of integrated circuit dies (e.g., with or without the bridge dies 80) are also possible in some embodiments.

As illustrated, the second integrated circuit dies 50B and the second bridge dies 80B are bonded to the first integrated circuit dies 50A in a dielectric-to-dielectric and metal-to-metal bonding configuration. The second integrated circuit dies 50B and the second bridge dies 80 are disposed face down such that respective front sides of the second integrated circuit dies 50B and the second bridge dies 80B face the dielectric bond layer 82 and the bond pads 84 along back-sides of the first integrated circuit dies 50A.

The dielectric layers 68 of the second integrated circuit dies 50B and the second bridge dies 80B may be directly bonded to the dielectric bond layer 82 along the first integrated circuit dies 50A. In some embodiments, the bonds between the dielectric bond layer 82 and each of the dielectric layers 68 are dielectric-to-dielectric bonds, such as oxide-to-oxide bonds, oxide-to-nitride bonds, or the like. In embodiments in which some of the second bridge dies 80B are dummy dies, portions of the dielectric bond layer 82 adjacent the dielectric layer 68 of the dummy die may be free of metal features, such that dielectric-to-dielectric bonds are formed at interfaces having widths extending the widths of the dummy dies.

The bonding process directly bonds the die connectors 66 of the second integrated circuit dies 50B and the second bridge dies 80B to the bond pads 84 through direct metal-to-metal bonding. Thus, the second integrated circuit dies 50B and the second bridge dies 80B are electrically and mechanically coupled to the first integrated circuit dies 50A. In some embodiments, interfaces between the second integrated circuit dies 50B and the first integrated circuit dies 50A also include dielectric-to-metal interfaces (e.g., where the die connectors 66 and the bond pads 84 are not perfectly aligned and/or have different widths). Similar dielectric-to-metal interfaces may result in the bonding of the second bridge dies 80B to the first integrated circuit dies 50A.

As an example, the dielectric-to-dielectric and metal-to-metal bonding processes start with applying a surface treatment to one or more of the dielectric layers 68 and/or the dielectric bond layer 82. The surface treatment may include a plasma treatment. The plasma treatment may be performed in a vacuum environment. After the plasma treatment, the surface treatment may further include a cleaning process (e.g., a rinse with deionized water or the like) that may be applied to one or both of the dielectric layers 68 and/or the dielectric bond layer 82. The die connectors 66 of the second integrated circuit dies 50B and the second bridge dies 80B are aligned to the corresponding bond pads 84 along the first integrated circuit dies 50A (e.g., such that outer side surfaces of the second bridge dies 80B are aligned with and coterminous with outer side surfaces of the first integrated circuit dies 50A). When the second integrated circuit dies 50B and the second bridge dies 80B are aligned with the first integrated circuit dies 50A, the die connectors 66 may overlap with corresponding bond pads 84 (e.g., and with corresponding conductive vias 70).

A pre-bonding step is performed during which the respective dielectric layers 68 and the respective die connectors 66 of the second integrated circuit dies 50B and of the second bridge dies 80B are placed in contact with the dielectric bond layer 82 and the corresponding bond pads 84 along the first integrated circuit dies 50A. The pre-bonding step may be performed at room temperature (e.g., from about 21° C. to about 25° C.). An anneal may be performed at a temperature in a range from about 150° C. to about 400° C., for a duration in a range from about 0.5 hours to about 3 hours. This causes metal in the die connectors 66 (e.g., copper) and metal in the bond pads 84 (e.g., copper) to inter-diffuse to each other, forming the direct metal-to-metal bonding. Other direct bonding processes (e.g., using adhesives, polymer-to-polymer bonding, or the like) may be used in some embodiments.

In some embodiments (not specifically illustrated), the second bridge dies 80B are bonded to the first integrated circuit dies 50A using solder connections (e.g., micro-bumps or the like). For example, the die connectors 66 of the second bridge dies 80B may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The die connectors 66 may include a conductive material such as solder, copper, aluminum, gold, nickel, silver, palladium, tin, the like, or a combination thereof. In some embodiments, the die connectors 66 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the die connectors 66 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments (not specifically illustrated), the dielectric layer 68 and the die connectors 66 of the second bridge dies 80B are directly bonded to the insulating layer 76 and the conductive vias 70, respectively, without forming the dielectric bond layer 82 and/or the bond pads 84 along the first integrated circuit dies 50A. This allows for overall thicknesses of the packaged semiconductor devices to be reduced. The insulating layer 76 can be formed with reduced thicknesses as compared with structures including the bond pads 84 between the die connectors 66 and the conductive vias 70. This reduces the thermal resistance of the integrated circuit dies 50, which improves heat dissipation in the packaged semiconductor devices.

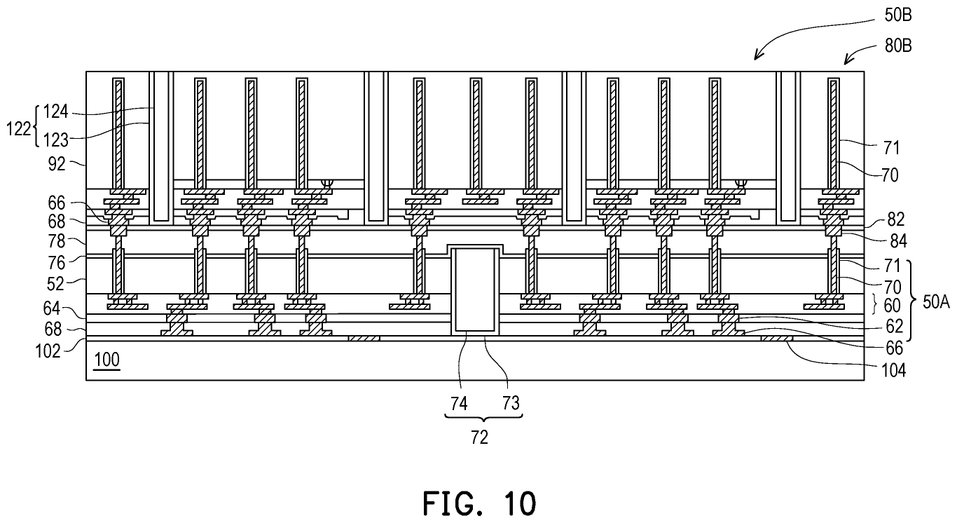

In FIG. 10, die spacers 122, which include a liner layer 123 and a gap-fill material 124, are formed on the second bridge dies 80B and the integrated circuit dies 50A, 50B in the gap regions 192, in accordance with some embodiments. The die spacer 122 (e.g., collectively, the liner layer 123 and the gap-fill material 124) may also be referred to as a gap-filling layer. The liner layers 123 may be formed of a dielectric material having good adhesion to the dielectric bond layer 82 (or the insulating layer 76), to sidewalls of the second bridge dies 80B, and to sidewalls of the second integrated circuit dies 50B. In some embodiments, the liner layer 123 is formed of a nitride-containing material, such as silicon nitride, or an oxide-containing material, such as silicon oxide. The liner layer 123 may be deposited as a conformal layer. For example, the liner layer 123 may be deposited by a conformal deposition process, such as ALD, CVD, or the like. In some embodiments, the gap-fill material 124 may be formed of a conductive material, and the liner layer 123 may be a barrier layer. In such embodiments, the liner layer 123 may be conformally deposited by CVD, ALD, PVD, thermal oxidation, a combination thereof, or the like. The liner layer 123 may be formed of an oxide, a nitride, a carbide, combinations thereof, or the like.

The gap-fill material 124 may be formed of a material different from the material of the liner layer 123. In some embodiments, the gap-fill material 124 may be formed of silicon oxide, silicon carbide, silicon oxynitride, silicon oxy-carbo-nitride, PSG, BSG, BPSG, or the like. For example, the gap-fill material 124 may be formed of any of the above oxide-containing materials, such as silicon oxide. The gap-fill material 124 may be formed using CVD, HDPCVD, flowable CVD, spin-on coating, or the like. In some embodiments, the gap-fill material 124 may be formed of a molding compound, epoxy, or the like. The gap-fill material 124 may be applied by compression molding, transfer molding, or the like. The gap-fill material 124 may fill remaining gaps between adjacent second bridge dies 80B and second integrated circuit dies 50B. After the liner layer 123 and the gap-fill material 124 are deposited, a planarization process, such as a CMP, a grinding process, an etch-back process, or the like is performed to remove excess portions of the liner layer 123 and the gap-fill material 124, forming the die spacers 122 and exposing the second bridge dies 80B and the second integrated circuit dies 50B.

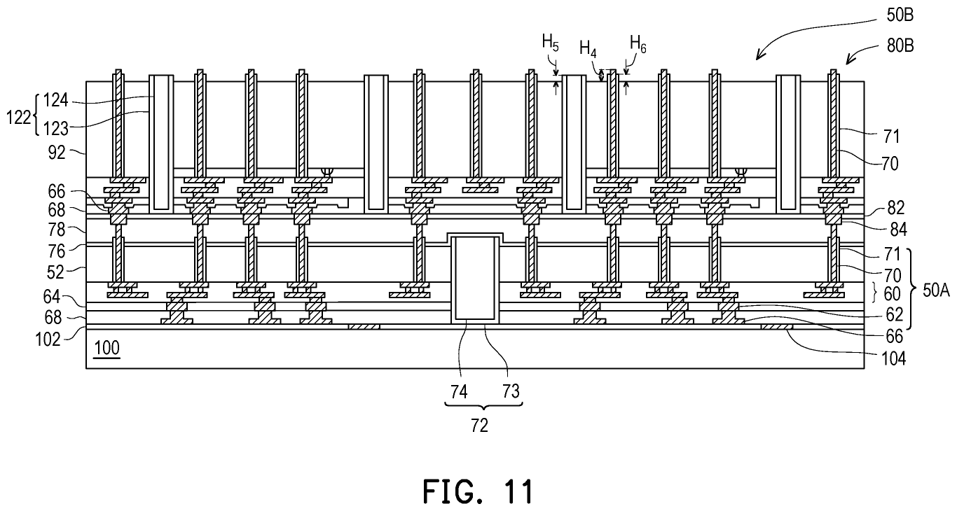

In FIG. 11, the semiconductor substrates 52 of the second integrated circuit dies 50B and the second bridge dies 80B are recessed so that the conductive vias 70 protrude above back surfaces of the semiconductor substrates 52. The semiconductor substrates 52 may be recessed by suitable etching processes, which may include isotropic etching processes such as wet etching, anisotropic etching process such as dry etching, or the like. The etching process may be selective for etching the material of the semiconductor substrates 52, while the conductive vias 70 remain substantially unetched. In some embodiments, the etching process may etch the via liner 71, the liner layer 123, and the gap-fill material 124 by greater etch rates than the conductive vias 70 and by lesser etch rates than the semiconductor substrate 52.

In some embodiments, after performing the etching process, the conductive vias 70 may protrude above the semiconductor substrates 52 by a height H₄ in a range from 0.6 μm to 1 μm. In addition, the die spacer 122 (e.g., the liner layer 123 and the gap-fill material 124) may protrude above the semiconductor substrates 52 by a height H₅, and the via liner 71 may protrude above the semiconductor substrate 52 by a height H₆. The heights H₅ and H₆ may be the same or different, wherein each is in a range from 0.2 μm to 0.6 μm. In some embodiments, the height H₅ is less than the height H₆. Note that the height H₄ may be the same or different as the height H₁, the heights H₅ may be the same or different as the heights H₂, and the height H₆ may be the same or different as the height H₃, as discussed above in connection with recessing the semiconductor substrates 52 of the integrated circuit dies 50A.

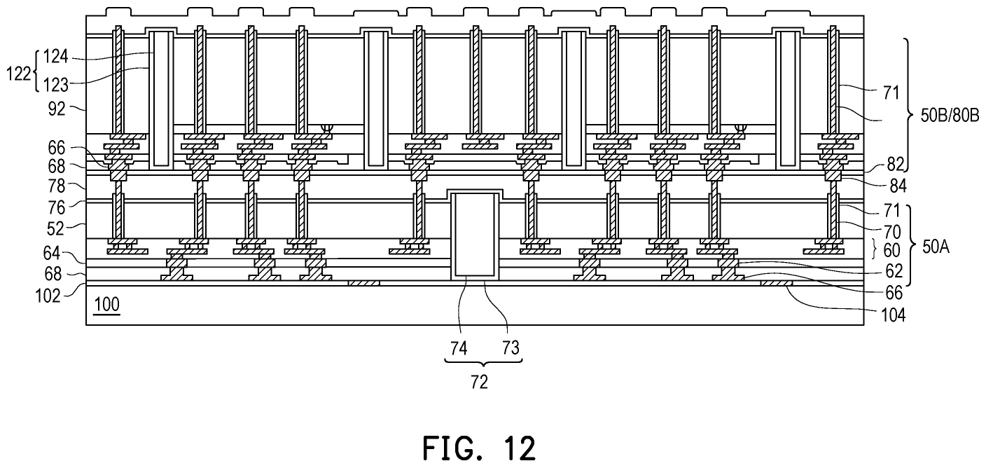

In FIG. 12, after recessing the semiconductor substrates 52, insulating layers, such as an insulating layer 126 and an insulating layer 128, may be formed over the recessed semiconductor substrates 52, as well as over and around the conductive vias 70. The insulating layers 126, 128 provide isolation between the conductive vias 70, and may be used in subsequent dielectric-to-dielectric bonding processes for attaching various other dies to the second integrated circuit dies 50B and the second bridge dies 80B. Each of the insulating layers 126, 128 is formed by depositing insulating material on the exposed upper surfaces (e.g., back-sides) of the second integrated circuit dies 50B and the second bridge dies 80B. The insulating material may be formed of silicon oxide, silicon carbide, silicon oxynitride, silicon oxycarbonitride, PSG, BSG, BPSG, the like, or a combination thereof. The insulating material may be deposited by CVD, ALD, spin-on coating, or the like.

For example, the insulating layer 126 may be silicon nitride or silicon oxide and conformally deposited over the semiconductor substrates 52 and the die spacers 122 (e.g., the liner layer 123 and the gap-fill material 124). Although not specifically illustrated, in some embodiments, the insulating layer 126 may also be deposited along exposed surfaces of the conductive vias 70 and the via liner 71. In some embodiments, the insulating layer 126 is formed as a thermal oxide and, optionally, nitridated in a post-deposition treatment process. The insulating layer 128 may be silicon oxide or silicon nitride (e.g., a same or different material as the insulating layer 126) and conformally deposited over the insulating layer 126. In accordance with some embodiments, the insulating layer 128 may have a thickness above the semiconductor substrates in a range from 1 μm to 2 μm and a thickness above the conductive vias 70 in a range from 1 μm to 2 μm.

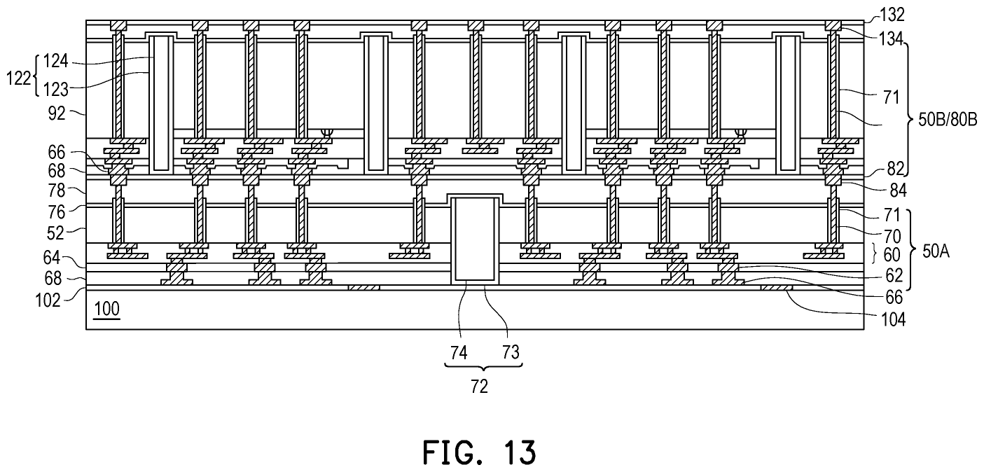

In FIG. 13, a planarization process is performed to level an upper surface of the insulating layer 128, and, optionally, a dielectric bond layer 132 and bond pads 134 are formed over the insulating layer 128 and the conductive vias 70. The planarization process may be a CMP, a grinding process, an etch-back process, or the like. In some embodiments, the planarization process is halted before reaching the conductive vias 70 or the planarization process may continue so that the insulating layer 128 is level with the conductive vias 70. As illustrated, after planarizing the insulating layer 128, a surface of the insulating layer 128 may be above top surfaces of the conductive vias 70, the insulating layer 126, and the die spacer 122 (e.g., the liner layer 123 and the gap-fill material 124). For example, in some embodiments, the insulating layer 128 may have a thickness above the semiconductor substrates 52 of the second integrated circuit dies 50B and the second bridge dies 50B in a range from 1 μm to 1.5 μm, the insulating layer 128 may have a thickness above the conductive vias 70 in a range from 0.2 μm to 0.9 μm, and the insulating layer 128 may have a thickness above the die spacer 122 (or above the insulating layer 126) in a range from 0.8 μm to 1.3 μm.

As discussed above, benefits are achieved by the top surfaces of the die spacers 122 (e.g., the liner layer 123 and the gap-fill material 124), the insulating layer 126 (if present) and the conductive vias 70 remaining covered by the insulating layer 128 during and after the planarization process. For example, the CMP and/or etch-back processes of the planarization process may be more efficient and result in a flatter planarized surface because the planarization process is performed on a single material rather than on multiple materials (e.g., having varying etch selectivities). As a result, the planarized surface of the structure (e.g., the upper surface of the insulating layer 128) is flatter and smoother than if the planarized surface included the insulating layer 128 as well as the gap-fill material 124, the liner layer 123, and/or the insulating layer 126.

In some embodiments, the dielectric bond layer 132 may be formed of an oxide (e.g., silicon oxide), a nitride (e.g., silicon nitride), an oxynitride (e.g., silicon oxynitride), or the like, similarly as described above in connection with the dielectric bond layer 82. Openings may then be formed through the dielectric bond layer 132 and partially through the insulating layer 128 to expose the conductive vias 60. The bond pads 134 are then formed in the openings, similarly as described above in connection with the bond pads 84. In some embodiments, the bond pads 134 may include dummy bond pads, which are not coupled to any metal features (e.g., the conductive vias 60) of the second integrated circuit dies 50B or the second bridge dies 80B.

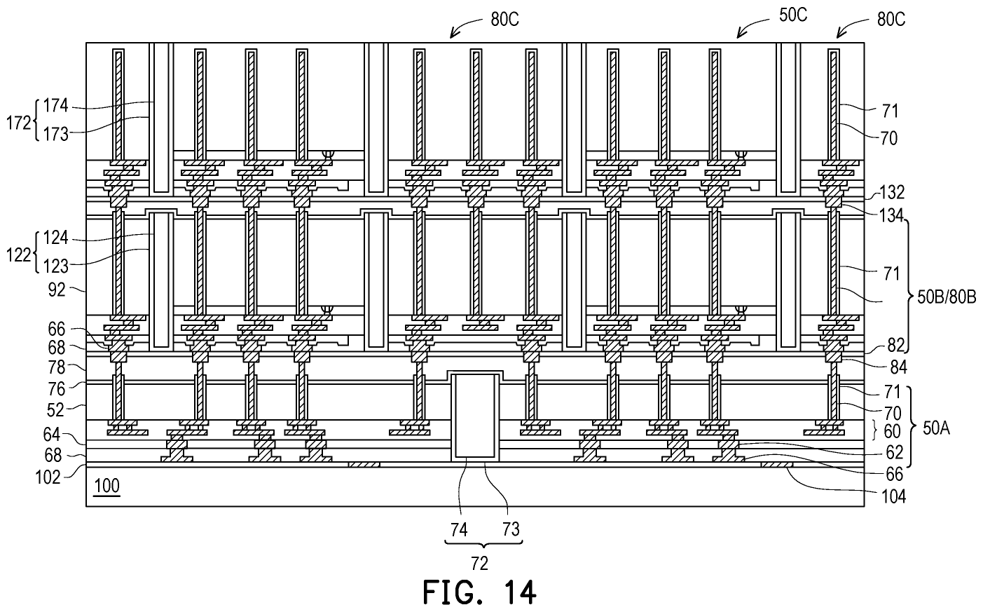

In FIG. 14, a third level of third integrated circuit dies 50C and third bridge dies 80C is bonded to the dielectric bond layer 132 and the bond pads 134 disposed along the second integrated circuit dies 50B and the second bridge dies 80B, similarly as described above in connection with bonding the second integrated circuit dies 50B and the second bridge dies 80B to the first integrated circuit dies 50A. In addition, die spacers 172 (e.g., also referred to as gap-filling layers) which include a liner layer 173 and a gap-fill material 174, are formed on and between the third integrated circuit dies 50C and the third bridge dies 80C. The die spacers 172 may be formed similarly as described above in connection with the die spacers 72, 122 (e.g., including the respective liner layers 73, 123 and the respective gap-fill materials 74, 124).

In FIG. 15, a support substrate 200 is attached to the third integrated circuit dies 50C and the third bridge dies 80C, in accordance with some embodiments. For example, a bonding layer 204 is formed on the third integrated circuit dies 50C, the third bridge dies 80C, and the die spacers 172 (e.g., the liner layer 173 and the gap-fill material 174). The bonding layer 204 may be an oxide layer, such as silicon oxide (e.g., an HDP oxide or the like). The bonding layer 204 may be deposited on the planarized upper surface of the structure using, for example, CVD, ALD, PVD, thermal oxidation, or the like. Other suitable materials may be used for the bonding layer 204.

As discussed above, the support substrate 200 may be bonded to the third integrated circuit dies 50C and the third bridge dies 80C by bonding the bonding layer 202 disposed along the support substrate 200 to the bonding layer 204 disposed along the third integrated circuit dies 50C, the third bridge dies 80C, and the die spacers 172. The support substrate 200 may be a glass support substrate, a ceramic support substrate, a wafer (e.g., a silicon wafer), or the like. The support substrate 200 may provide structural support during subsequent processing steps and in the completed device.

In some embodiments, the support substrate 200 may be bonded to the third integrated circuit dies 50C and the third bridge dies 80C using a suitable technique, such as dielectric-to-dielectric bonding or the like. The bonding layer 102 may be an oxide layer, such as silicon oxide (e.g., an HDP oxide or the like), that is formed on a surface of the support substrate 200 prior to bonding using, for example, CVD, ALD, PVD, thermal oxidation, or the like. Other suitable materials may be used for the bonding layer 202. The dielectric-to-dielectric bonding process may be the same as or similar to the dielectric-to-dielectric bonding process described above in connection with bonding the carrier substrate 100 to the first integrated circuit dies 50A (see FIG. 2).

In some embodiments (not specifically illustrated), the third integrated circuit dies 50C and the third bridge dies 80C do not include conductive vias 70 because the external electrical connection is made to and through the first integrated circuit dies 50A. In some embodiments (also not specifically illustrated), external electrical connection is made to the conductive vias 70 of the third integrated circuit dies 50C and/or the bridge dies 80C instead of attaching the support substrate 200.

In the embodiments described above, the integrated circuit dies 50 and the bridge dies 80 are bonded to one another using various combinations of dielectric-to-dielectric bonds and metal-to-metal bonds, the carrier substrate 100 is bonded to the first integrated circuit dies 50A by dielectric-to-dielectric bonds (e.g., fusion bonding), and the support substrate 200 is bonded to the third integrated circuit dies 50C and the third bridge dies 80C by dielectric-to-dielectric bonds (e.g., fusion bonding). In addition, as discussed above, the dielectric bond layers 82, 132 and the respective bond pads 84, 134 may be formed to facilitate attachment of the integrated circuit dies 50 and the bridge dies 80 to one another.

In some embodiments (not specifically illustrated), the integrated circuit dies 50 and/or the bridge dies 80 may be attached in the packaged semiconductor device without forming the dielectric bond layers 82, 132 and the bond pads 84, 134. For example, the die connectors 66 (or other conductive features) of the integrated circuit dies 50 and/or the bridge dies 80 may be bonded directly to the conductive vias 60 (or other conductive features) of the other integrated circuit dies 50 and bridge dies 80. Further, the dielectric layers 68 may be bonded directly to the corresponding insulating layers 78, 128. By directly coupling the die connectors 66 and the dielectric layers 68 to the conductive vias 70 and the insulating layers 76, 126, without additional bond pads and/or dielectric layers formed there between, the packaged semiconductor device may have a reduced overall thickness. In addition, eliminating those steps and additional layers may also reduce costs and increase throughput of the packaged semiconductor device.

Although not specifically illustrated, the packaged semiconductor device may undergo further processing, in accordance with some embodiments. In particular, after attaching the support substrate 200, the carrier substrate 100 may be removed and external connectors may be formed over the die connectors 66 of the first integrated circuit dies 50A. For example, the carrier substrate 100 and the bonding layer 102 may be removed to expose the die connectors 66 of the first integrated circuit dies 50A. A dielectric layer (e.g., a passivation layer) may then be formed along the first integrated circuit dies 50A and the exposed die spacer 72 (e.g., the liner layer 73). The dielectric layer may be patterned to form openings to the die connectors 66, and under-bump metallurgies (UBMs) may be formed in the openings using a suitable process. External connectors may then be formed on the UBMs. The external connectors may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. If formed at a wafer level, the packaged semiconductor devices may be singulated from one another and attached to other components, such as being incorporated into electronic devices.

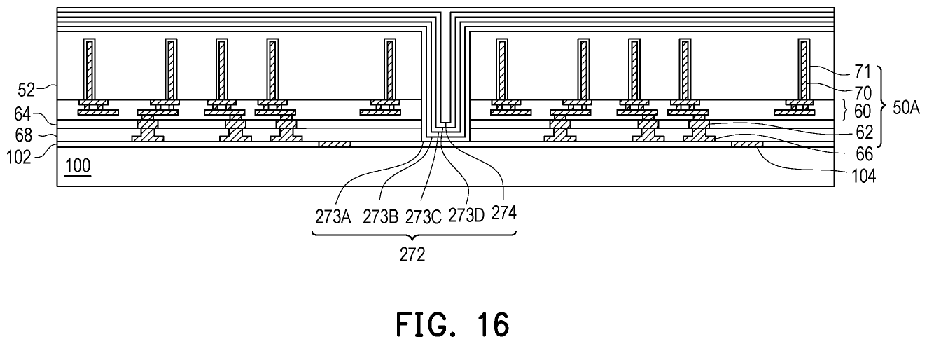

Referring to FIGS. 16-18, in accordance with some embodiments, packaged semiconductor devices may be formed with variations in formation of the die spacers. The resulting die spacers may be formed with improves strength and reliability, thereby giving the packaged semiconductor device improved durability and performance. The packaged semiconductor device may be formed similarly as the various processing steps described above, unless otherwise specified.

In FIG. 16, after attaching the first integrated circuit dies 50A to the carrier substrate 100 (see FIG. 2), a die spacer 272 is formed by conformally depositing a plurality of dielectric layers 273 over and between the first integrated circuit dies 50A followed by depositing a gap-fill material 274 to fill in a remaining space between the first integrated circuit dies 50A. The plurality of dielectric layers 273 and the gap-fill material 274 may be deposited by ALD, CVD, or the like. In some embodiments, the plurality of dielectric layers 273 are deposited with alternating compositions (e.g., chemical compositions). As illustrated, each of the plurality of dielectric layers 273 may be deposited as inset U-shapes. After depositing the plurality of dielectric layers 273, the gap-fill material 274 may be deposited as a T-shape within the U-shape of a last of the dielectric layers 273.

For example, each of the plurality of dielectric layers 273 may be silicon nitride, silicon oxide, silicon carbide, silicon carbonitride, silicon oxynitride, or the like. In accordance with some embodiments, a first dielectric layer 273A may be deposited as a first composition, and a second dielectric layer 273B may then be deposited as a second composition. A third dielectric layer 273C may then be deposited with a same composition as the first dielectric layer 273A, and a fourth dielectric layer 273D may be deposited with a same composition as the second dielectric layer 273B. For example, in embodiments in which additional dielectric layers 273 are deposited (not specifically illustrates), the additional dielectric layers 273 may continue the pattern of alternating compositions. The gap-fill material 274 may then be selected to continue the alternating compositions pattern. For example, in some embodiments, the first composition may be silicon nitride, and the second composition may be silicon carbide, silicon oxide, or silicon oxynitride. In addition, in some embodiments, the first composition may be silicon oxide, and the second composition may be silicon carbide, silicon nitride, or silicon carbonitride.

It should be appreciated that other combinations of compositions of the plurality of dielectric layers 273 and the gap-fill material 274 may be used to form the die spacer 272. For example, the plurality of dielectric layers may alternate between any others of the above-listed oxygen-containing layers and any others of the above-listed carbon-containing layer, between any others of the oxygen-containing layers and any others of the nitrogen-containing layers, or between any others of the carbon-containing layers and any others of the nitrogen-containing layers. In addition, three or more types of compositions may be used for the plurality of dielectric layers.

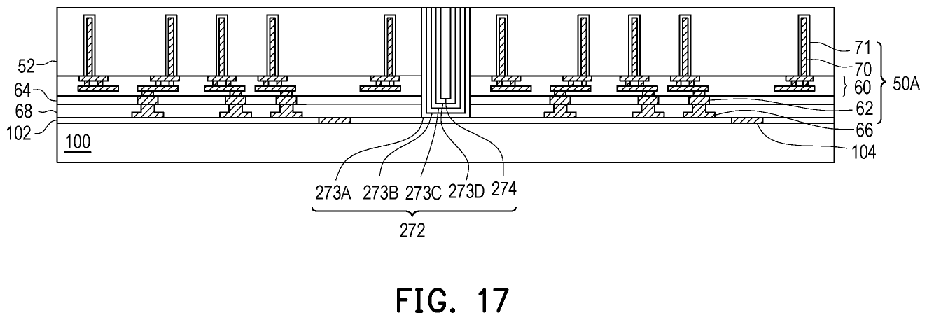

In FIG. 17, a planarization process is performed on the die spacer 272 (e.g., the plurality of dielectric layers 273 and the gap-fill material 274) to be level with the first integrated circuit dies 50A. For example, the planarization process may include a CMP, a grinding process, an etch-back process, the like, or combinations thereof, and is performed to remove excess portions of the gap-fill material 274 and the plurality of dielectric layers 273, thereby exposing the semiconductor substrates 52 of the first integrated circuit dies 50A, similarly as described above (see FIG. 3). Although not specifically illustrated, subsequent processing steps may be performed, similarly as described above in connection with FIGS. 4-8.

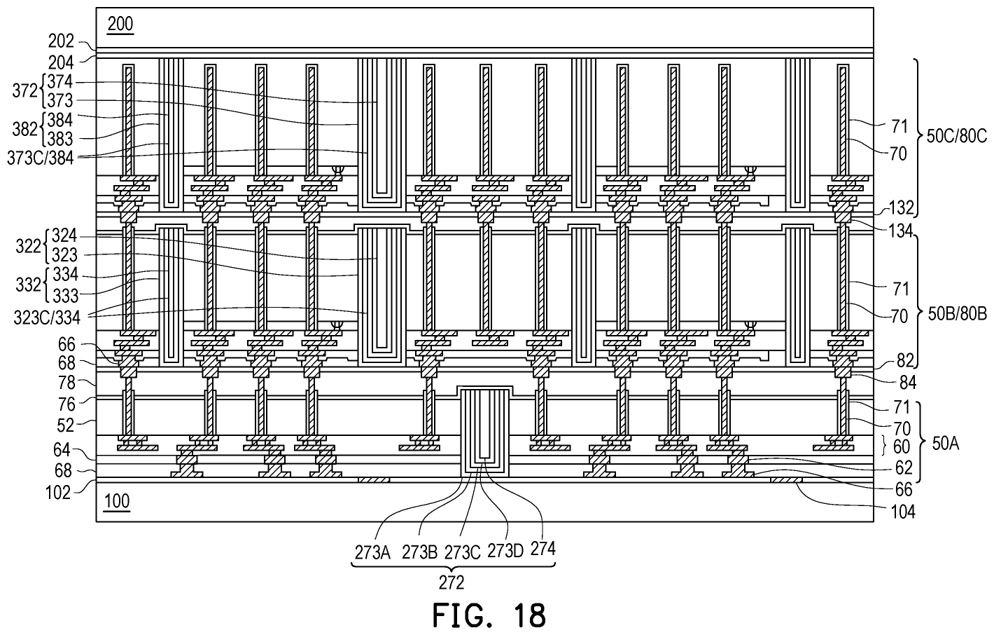

In FIG. 18, integrated circuit dies 50B, 50C and bridge dies 80B, 80C may be attached, similarly as described above in connection with FIGS. 9-14. As illustrated, die spacers 322, 332 may be formed between the second integrated circuit dies 50B and the second bridge dies 80B, similarly as described in connection with FIGS. 16-17 (e.g., the die spacer 272). In addition, die spacers 372, 382 may be formed between the third integrated circuit dies 50C and the third bridge dies 80C, similarly as described in connection with FIGS. 16-17 (e.g., the die spacer 272). As further illustrated, wide die spacers 322, 372 are formed in wide gap regions, and narrow die spacers 332, 382 are formed in narrow gap regions.

As illustrated, the wide die spacers 322 (e.g., within the second level which includes the second integrated circuit dies 50B and the second bridge dies 80B) may be formed similarly as described in connection with the die spacers 272. For example, the wide die spacers 322 may have a same number of the plurality of dielectric layers 323 before depositing the gap-fill material 324 as compared with the plurality of dielectric layers 273 and the gap-fill material 274 of the die spacers 272. In addition, the narrow die spacers 332 may be formed with a fewer number of the plurality of dielectric layers 333 (e.g., as compared with the die spacers 273 and the wide die spacers 323) before depositing the gap-fill material 334. For example, in some embodiments, the third dielectric layer 323C of the wide die spacers 322 may be formed simultaneously with the gap-fill material 334 of the narrow die spacers 332.

Similarly, the wide die spacers 372 (e.g., within the third level which includes the third integrated circuit dies 50C and the third bridge dies 80C) may be formed similarly as described in connection with the die spacers 272. For example, the wide die spacers 373 may have a same number of the plurality of dielectric layers 373 before depositing the gap-fill material 374 as compared with the plurality of dielectric layers 273 and the gap-fill material 274 of the die spacers 272. In addition, the narrow die spacers 382 may be formed with a fewer number of the plurality of dielectric layers 383 (e.g., as compared with the die spacers 273 and the wide die spacers 323, 373). For example, in some embodiments, the third dielectric layer 373C of the wide die spacers 372 may be formed simultaneously with the gap-fill material 384 of the narrow die spacers 382.

In addition, subsequent processing steps, such as attaching the support substrate 200, may be performed as described above in connection with FIG. 15. Moreover, as discussed above, the packaged semiconductor device may undergo subsequent processing steps not illustrated herein, including formation of UBMs and external connectors, singulation, and/or attachment to other components, such as being incorporated into electronic devices.

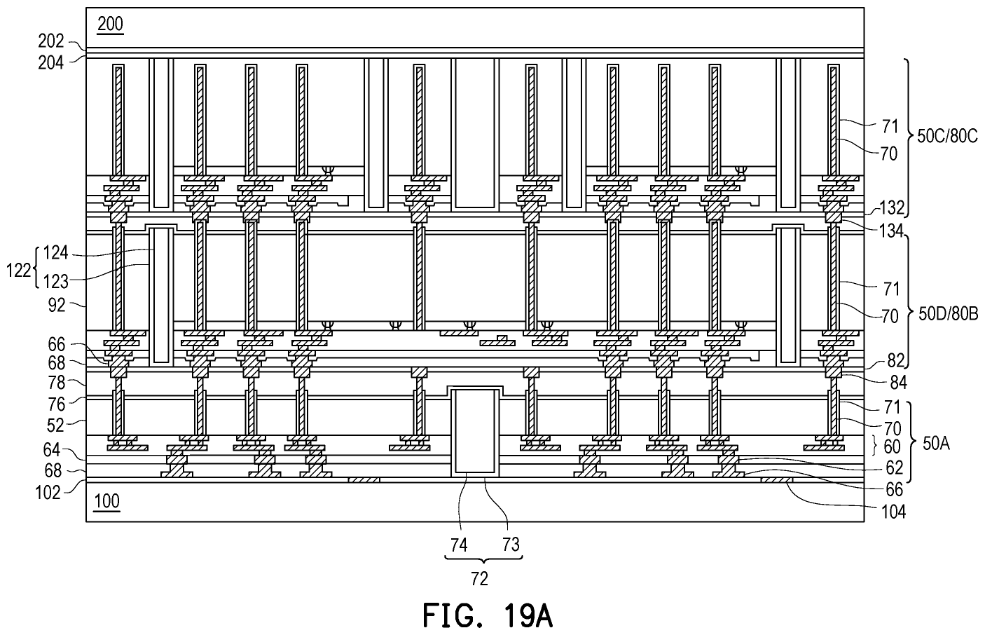

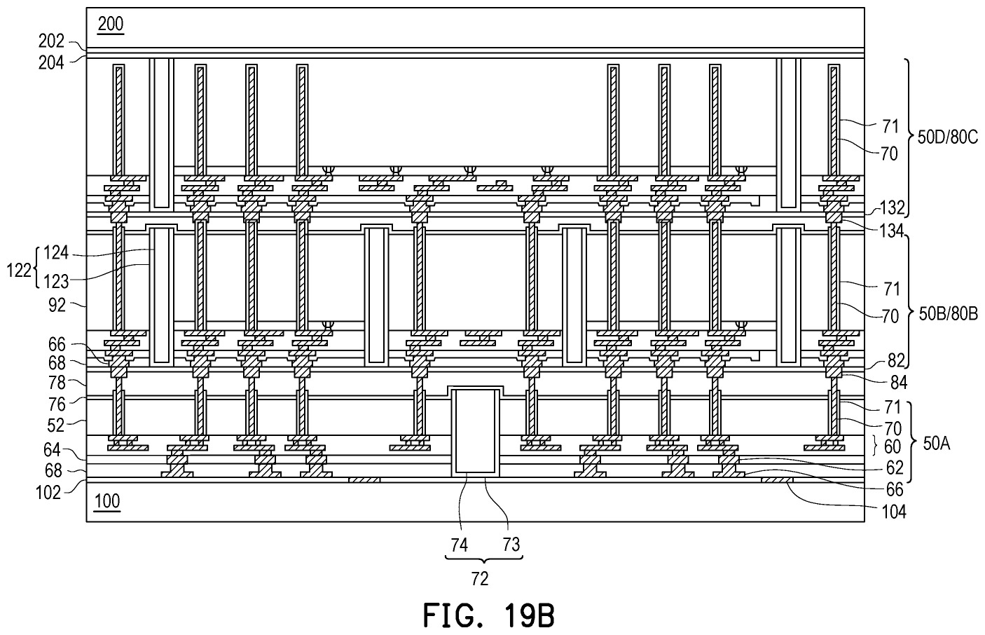

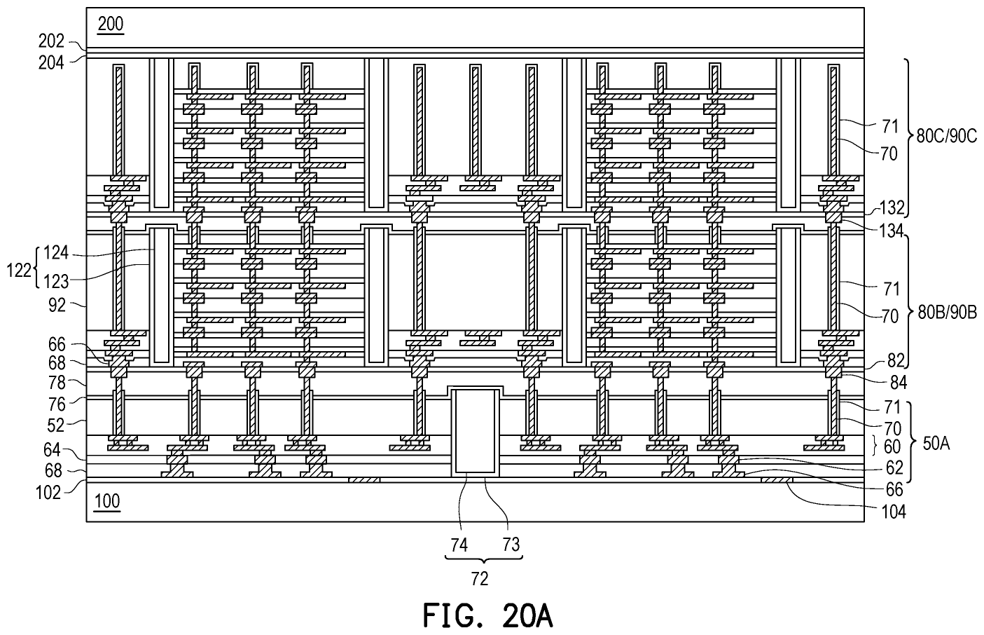

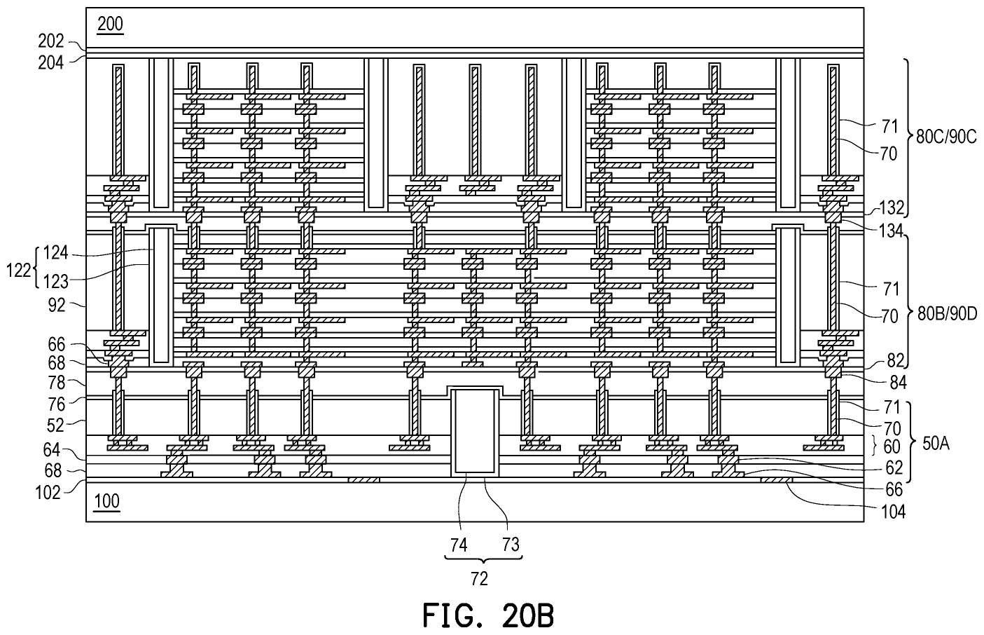

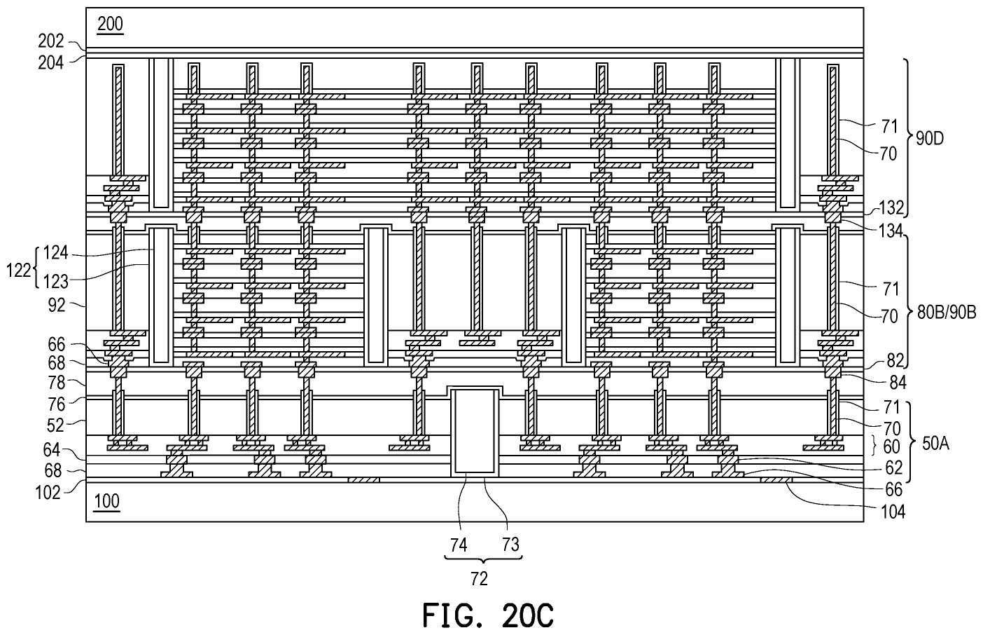

Referring to FIGS. 19A-20C, in accordance with some embodiments, the packaged semiconductor device may be formed with variations in the integrated circuit dies 50 and the bridge dies 80. The variations may facilitate particular functionality benefits. The following packaged semiconductor devices may be formed similarly as the various processing steps described above, unless otherwise specified, including the variations in forming the die spacers 72, 122, 172, 272.

In FIGS. 19A and 19B, packaged semiconductor devices may include an expanded integrated circuit die 50D (e.g., having direct electrical connections with more than one of the integrated circuit dies 50 and/or the bridge dies 80), in accordance with some embodiments. As illustrated, the expanded integrated circuit die 50D may have a greater width than the other integrated circuit dies 50 and the bridge dies 80. In some embodiments (not specifically illustrated), the expanded integrated circuit die 50D may be a same width as the other integrated circuit dies 50 while being shifted in order to bridge and have direct electrical connections with more than one of the integrated circuit dies 50 and/or bridge dies 80 above or below. Other dies, such as third bridge dies 80C, may be attached laterally adjacent to the expanded integrated circuit die 50D, or the expanded integrated circuit die 50D may span all or most of a width of the packaged semiconductor device. Although illustrated with three levels of integrated circuit dies 50 and bridge dies 80, the packaged semiconductor device may have two levels or more than three levels. In addition, expanded integrated circuit dies 50D may be attached to more than one level of the packaged semiconductor device.

Referring to FIG. 19A, the expanded integrated circuit die 50D may be on the second level of the packaged semiconductor device. As such, the expanded integrated circuit die 50D may have immediate connections (e.g., direct connections through the bond pads 84) with two or more of the underlying first integrated circuit dies 50A. In addition, the expanded integrated circuit die 50D may have immediate connections (e.g., direct connections through the bond pads 134) with two or more of the overlying third integrated circuit dies 50C and the bridge dies 80C.

Referring to FIG. 19B, the expanded integrated circuit die 50D may be on the third level of the packaged semiconductor device. As such, the expanded integrated circuit die 50D may have immediate connections (e.g., direct connections through the bond pads 134) with two or more of the underlying second integrated circuit dies 50B and the bridge dies 80B. In addition, the support substrate 200 may be attached to the expanded integrated circuit die 50D (and the third bridge dies 80C, if present).

In FIGS. 20A-20C, packaged semiconductor devices may include die stacks 90, for example, in place of one or more of the integrated circuit dies 50 from any of the embodiments described above. As discussed above (see FIG. 1C), each die stack 90 may include a plurality of integrated circuit dies 50 or a combination of integrated circuit dies 50 and bridge dies 80 in a stacked formation.

For example, FIG. 20A illustrates a packaged semiconductor device similar to the device described in connection with FIG. 15, wherein the second integrated circuit dies 50B are substituted with second die stacks 90B and the third integrated circuit dies 50C are substituted with third die stacks 90C. In addition, FIG. 20B illustrates a packaged semiconductor device similar to the device described in connection with FIG. 19A, wherein the expanded integrated circuit die 50D is substituted with an expanded die stack 90D and the third integrated circuit dies 50C are substituted with third die stacks 90C. Further, FIG. 20C illustrates a packaged semiconductor device similar to the device described in connection with FIG. 19B, wherein the expanded integrated circuit die 50D is substituted with an expanded die stack 90D and the second integrated circuit dies 50B are substituted with second die stacks 90B.

Embodiments may achieve various advantages. As discussed above, after attaching the first integrated circuit dies 50A to the carrier substrate 100, the first integrated circuit dies 50A undergo processing in preparation for attaching the second integrated circuit dies 50B to the first integrated circuit dies 50A. For example, semiconductor substrates 52 of the first integrated circuit dies 50A are recessed to expose the conductive vias 70, which then protrude from the semiconductor substrates 52. The die spacers 72 may also protrude from the semiconductor substrates 52 of the first integrated circuit dies 50A. An insulating layer 78 (e.g., an oxide layer) is deposited over the first integrated circuit dies 50A with a sufficient thickness that the protruding conductive vias 70 and die spacers 72 are covered. A planarization process is performed to give the insulating layer 78 a flat upper surface that remains covering the semiconductor substrates 52, the conductive vias 70, and the die spacers 72. The insulating layer 78 remaining above the other features ensures that the etchants included in the planarization process etch only material of the insulating layer 78, thereby achieving the flat upper surface more effectively and more efficiently. The resulting flatter surface improves efficiency and yield of subsequent steps, such as formation of an overlying dielectric bond layer 82 and bond pads 84. Furthermore, bonding of the second integrated circuit dies 50B (and, optionally, second bridge dies 80B or dummy dies) is improved. The packaged semiconductor device may undergo further processing, including similar steps to improve attachment of third integrated circuit dies 50C. In accordance with the various embodiments, the packaged semiconductor device may be assembled at greater efficiency and increased yield (e.g., thereby reducing costs) and with an improved performance.

In an embodiment, a method includes: attaching a first die and a second die to a substrate, the first die comprising a conductive via; forming a die spacer between the first die and the second die; thinning the first die and the second die, wherein after thinning the first die and the second die, the die spacer protrudes a first height above an upper surface of the first die; depositing an insulating layer over the first die and the second die; planarizing the insulating layer, wherein after planarizing, the insulating layer has a first thickness above the first die and a second thickness above the die spacer; attaching a third die and a fourth die to the first die and the second die; and attaching a support substrate to the third die and the fourth die. In another embodiment, after thinning the first die and the second die, the conductive via of the first die protrudes a second height above the upper surface of the first die. In another embodiment, the second height is greater than the first height. In another embodiment, the method further includes: depositing a dielectric bond layer over the insulating layer; and forming a bond pad in the dielectric bond layer, the bond pad being electrically coupled to the conductive via. In another embodiment, attaching the third die and the fourth die comprises dielectric-to-dielectric and metal-to-metal bonding a die connector and a dielectric layer to the bond pad and the dielectric bond layer, respectively. In another embodiment, the first thickness is greater than the second thickness. In another embodiment, the first die comprises a via liner around the conductive via, and wherein after thinning the first die and the second die, the via liner is a third height above the upper surface of the first die, the second height being greater than the third height. In another embodiment, the first height is the same as the third height. In another embodiment, forming the die spacer includes: conformally depositing a first dielectric layer over and between the first die and the second die, the first dielectric layer being a first composition; conformally depositing a second dielectric layer over the first dielectric layer, the second dielectric layer being a second composition; conformally depositing a third dielectric layer over the second dielectric layer, the third dielectric layer being the first composition; and conformally depositing a fourth dielectric layer over the third dielectric layer, the fourth dielectric layer being the second composition. In another embodiment, the first composition is silicon oxide, and wherein the second composition is silicon nitride.

In an embodiment, a semiconductor package includes: a first die over a first substrate, the first die comprising a first conductive via extending through a first semiconductor substrate, the first conductive via protruding above the first semiconductor substrate by a first height; a second die over the substrate and laterally displaced from the first die, the second die comprising a second conductive via extending through a second semiconductor substrate, the second conductive via protruding above the second semiconductor substrate by a second height; a first die spacer over the substrate and between the first die and the second die, the first die spacer protruding above the first substrate by a third height; an insulating layer over and around sidewalls of the first conductive via, the second conductive via, and the first die spacer; a third die over the first die and the second die, the third die being electrically connected to the first die; a fourth die laterally displaced from the third die; and a second die spacer between the third die and the fourth die, lowermost surfaces of the third die, the fourth die, and the second die spacer being level. In another embodiment, the second die spacer protrudes above a third semiconductor substrate of the third die by a third height, wherein the third height is less than the first height and the second height. In another embodiment, the semiconductor package further includes a dielectric bond layer and a bond pad interposed between the first die and the third die, uppermost surfaces of the dielectric bond layer and the bond pad being in physical contact with the lowermost surfaces of the third die, the fourth die, and the second die spacer. In another embodiment, wherein the third die comprises a stack of multiple dies, and wherein sidewalls of the multiple dies are level. In another embodiment, the fourth die is a bridge die being free of active devices, and wherein the bridge die is electrically connected to the fourth die. In another embodiment, the semiconductor package further includes a fifth die over the third die and the fourth die, the fifth die being electrically connected to the third die and the fourth die.

In an embodiment, a semiconductor package includes: a first die and a second die over a substrate, an active side of the first die facing the substrate, the first die comprising: an interconnect structure proximal to the substrate; a semiconductor substrate over the interconnect structure, a most distal surface of the semiconductor substrate being a first distance from the substrate; a conductive via extending through the semiconductor substrate, a most distal point of the conductive via being a second distance from the substrate; and a dielectric via liner around the conductive via and interposed between the conductive via and the semiconductor substrate, a most distal point of the dielectric via liner being a third distance from the substrate; a die spacer interposed between sidewalls of the first die and the second die, a lower surface of the first die being level with a lower surface of the die spacer, a most distal point of the die spacer being a fourth distance from the substrate, the second distance being greater than the fourth distance, the fourth distance being greater than the first distance; and an insulating layer over the first die and the second die, a most distal surface of the insulating layer being a fifth distance from the substrate, the fifth distance being greater than the second distance. In another embodiment, the third distance and the fourth distance are the same. In another embodiment, the die spacer comprises a plurality of U-shaped dielectric layers and an innermost dielectric layer. In another embodiment, the plurality of U-shaped dielectric layers and the innermost dielectric layer have alternating chemical compositions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
attaching a first die and a second die to a substrate, the first die comprising a conductive via;
forming a die spacer between the first die and the second die;
thinning the first die and the second die, wherein after thinning the first die and the second die, the die spacer protrudes a first height above an upper surface of the first die;
depositing an insulating layer over the first die and the second die;
planarizing the insulating layer, wherein after planarizing, the insulating layer has a first thickness above the first die and a second thickness above the die spacer;
attaching a third die and a fourth die to the first die and the second die; and
attaching a support substrate to the third die and the fourth die.

2. The method of claim 1, wherein after thinning the first die and the second die, the conductive via of the first die protrudes a second height above the upper surface of the first die.

3. The method of claim 2, wherein the second height is greater than the first height.

4. The method of claim 2, further comprising:
depositing a dielectric bond layer over the insulating layer; and
forming a bond pad in the dielectric bond layer, the bond pad being electrically coupled to the conductive via.

5. The method of claim 4, wherein attaching the third die and the fourth die comprises dielectric-to-dielectric and metal-to-metal bonding a die connector and a dielectric layer to the bond pad and the dielectric bond layer, respectively.

6. The method of claim 1, wherein the first thickness is greater than the second thickness.

7. The method of claim 1, wherein the first die comprises a via liner around the conductive via, and wherein after thinning the first die and the second die, the via liner is a third height above the upper surface of the first die, the second height being greater than the third height.

8. The method of claim 7, wherein the first height is the same as the third height.

9. The method of claim 1, wherein forming the die spacer comprises:
conformally depositing a first dielectric layer over and between the first die and the second die, the first dielectric layer being a first composition;
conformally depositing a second dielectric layer over the first dielectric layer, the second dielectric layer being a second composition;
conformally depositing a third dielectric layer over the second dielectric layer, the third dielectric layer being the first composition; and
conformally depositing a fourth dielectric layer over the third dielectric layer, the fourth dielectric layer being the second composition.

10. The method of claim 9, wherein the first composition is silicon oxide, and wherein the second composition is silicon nitride.

11. A semiconductor package, comprising:
a first die over a first substrate, the first die comprising a first conductive via extending through a first semiconductor substrate, the first conductive via protruding above the first semiconductor substrate by a first height;
a second die over the substrate and laterally displaced from the first die, the second die comprising a second conductive via extending through a second semiconductor substrate, the second conductive via protruding above the second semiconductor substrate by a second height;
a first die spacer over the substrate and between the first die and the second die, the first die spacer protruding above the first substrate by a third height;
an insulating layer over and around sidewalls of the first conductive via, the second conductive via, and the first die spacer;
a third die over the first die and the second die, the third die being electrically connected to the first die;
a fourth die laterally displaced from the third die; and
a second die spacer between the third die and the fourth die, lowermost surfaces of the third die, the fourth die, and the second die spacer being level.

12. The semiconductor package of claim 11, wherein the second die spacer protrudes above a third semiconductor substrate of the third die by a third height, wherein the third height is less than the first height and the second height.

13. The semiconductor package of claim 11, further comprising a dielectric bond layer and a bond pad interposed between the first die and the third die, uppermost surfaces of the dielectric bond layer and the bond pad being in physical contact with the lowermost surfaces of the third die, the fourth die, and the second die spacer.

14. The semiconductor package of claim 11, wherein the third die comprises a stack of multiple dies, and wherein sidewalls of the multiple dies are level.

15. The semiconductor package of claim 11, wherein the fourth die is a bridge die being free of active devices, and wherein the bridge die is electrically connected to the fourth die.

16. The semiconductor package of claim 15, further comprising a fifth die over the third die and the fourth die, the fifth die being electrically connected to the third die and the fourth die.

17. A semiconductor package, comprising:
a first die and a second die over a substrate, an active side of the first die facing the substrate, the first die comprising:
an interconnect structure proximal to the substrate;
a semiconductor substrate over the interconnect structure, a most distal surface of the semiconductor substrate being a first distance from the substrate;
a conductive via extending through the semiconductor substrate, a most distal point of the conductive via being a second distance from the substrate; and
a dielectric via liner around the conductive via and interposed between the conductive via and the semiconductor substrate, a most distal point of the dielectric via liner being a third distance from the substrate;
a die spacer interposed between sidewalls of the first die and the second die, a lower surface of the first die being level with a lower surface of the die spacer, a most distal point of the die spacer being a fourth distance from the substrate, the second distance being greater than the fourth distance, the fourth distance being greater than the first distance; and
an insulating layer over the first die and the second die, a most distal surface of the insulating layer being a fifth distance from the substrate, the fifth distance being greater than the second distance.

18. The semiconductor package of claim 17, wherein the third distance and the fourth distance are the same.

19. The semiconductor package of claim 17, wherein the die spacer comprises a plurality of U-shaped dielectric layers and an innermost dielectric layer.

20. The semiconductor package of claim 19, wherein the plurality of U-shaped dielectric layers and the innermost dielectric layer have alternating chemical compositions.
